(19) United States
(12) Patent Application Publication
(10) Pub. No.: US 2007/0035321 A1
(43) Pub. Date: Feb. 15, 2007

(54) Device and method for testing mixed-signal circuits

(76) Inventors: Emanuel Gorodetsky, Alfei Menashe (IL); Azriel Machtiger, Herzlia (IL)

Correspondence Address: PEARL COHEN ZEDEK, LLP;PEARL COHEN ZEDEK LATZER, LLP, 1500 BROADWAY 12TH FLOOR, NEW YORK, NY, 10036, US

(21) Appl. No.: 11/200,135

(22) Filed: Aug. 10, 2005

(51) Int. Cl. G01R 31/02

(52) U.S. Cl. 324/761

(57) ABSTRACT

A method and circuit for expanding boundary scan testing capability to mixed-signal electronic circuit boards and to mixed-signal functional integrated circuit (IC) cores. The integrated circuit may include, for example, a pin selection coder circuitry and a pin multiplexing circuitry and may be provided with, for example, two serially connected test access port (TAP) circuitries.

### FIELD OF THE INVENTION

This invention relates to a method and apparatus for in-circuit testing, for example, real-time and off-line continuous monitoring of printed circuit boards and integrated circuit cores in a mixed-signal environment, for example, having both digital and analog signals.

### BACKGROUND OF THE INVENTION

Printed Circuit (“PC”) boards populated with Integrated Circuits (“IC”) may get smaller and more dense and ICs may become more complicated and occupied with functions, and it may also become more difficult to quickly and exhaustive diagnose faults and debugging of both PCs and ICs, as well as interconnection between them, for example Ball-Grid-Array (“BGA”) packages, Flip Chips or any other advanced package type. For example, as shown in FIG. 1, a BGA packages 11 (bottom view 10) may have an array of solder pads that are hidden from view and that may be difficult to probe when the pads are soldered to a multilayer PC board 12. It may be difficult or impossible to physically probe for visual of other verification of the signal level, an IC pin (or, for example, node 13 between BGA 11 pins 15 via PC board 12 internal or hidden layer) with, for example, test equipment 14. A signal probing in a PC board is a high priority need in a board and system functional testing and debug. Similar situation may happen in ICs with access restrictions for internal (in-core) testing and debug as semiconductor packaging density continues to increase.

The increasing trend to integrate greater capability into ICs resulting in embedded complexities has significantly reduced the effectiveness of the present in-circuit testing (ICT) or flying probe methods at the board level via a “bed-of-nails” interface The lack of signal probing pads (or test points) on a PC board may be due to the fact that ICs are densely populated on the both sides of state-of-the-art multilayer board as illustrated in FIG. 1 of because the Integrated Circuit is filly occupied with functions. This may exacerbate the problem of access to test points because physical test probes may not be able to penetrate several layers on a PC board, to probe dedicated pads and/or test points, or not available on the external I/O pins of the IC for in-core IC testing. Physical access for testing of manufacturing defects may be limited when BGA and other leadless packages are assembled. To access analog test points, however, external and expensive ICT testers and other test equipment may still be utilized, and the PC board layout and shielding may accommodate external probing. The densely populated, multilayer mixed-signal PC board and IC probing on debug stage and in the manufacturing test may be an ongoing challenge, just as in-core testing of ICs with accompanying pin count penalty or other package restrictions.

One way to implement the contactless signal level or waveform probing and insertion, as well as in-circuit analog measurements, is defined in the “IEEE Standard for a Mixed-Signal Test Bus”, approved in 1999 by the Institute for Electrical and Electronic Engineers (IEEE), which is also known as IEEE standard 1149.4-1999 (also referred to herein as “1149.4”). The general architecture of one example IC designed according to 1149.4 is shown in FIG. 2. This standard requires one or more shift register cells or modules 20 and 22 (also known as boundary scan register or “BSR”) per IC pin 21 and 23, and shifts boundary scan data into a BSR via a pin marked TDI 28 and out through a pin marked TDO 29. The BSR cells may be implemented by means of digital boundary modules (also referred to herein as “DBM”) 20, associated with digital input/output (I/O) pins 21, and analog boundary modules (also referred to herein as “ABM”) 22, associated with analog I/O pins 23. A Test Control Block, that also includes a Test Access Port (also referred to herein as “TAP”) 24, may be provided to facilitate both digital and analog boundary scan testing. Test Bus Interface Circuit (also referred to herein as “TBIC”) 25 may connect and control, for example, two internal test buses AB1 and AB2 26 to, for example, two external analog buses via external pins AT1 and AT2 27. The 1149.4 defines an analog bus that may connect, within an IC that equipped with such a circuitry, to the external pins AT1/2 27 of the IC and may permit (with, for example, a PROBE instruction) an analog pin 23 signal level or waveform delivery via the ABM 22, via one of internal test buses AB1/2 26, via TBIC 25 to one of external IC analog bus pins AT1/2 27. This may permit a signal level or waveform of one of IC external analog pins 23 to be monitored (e.g., probed) by external (to the IC and the board) test equipment that may be connected to one of IC external (and the PC board external) analog bus pins AT1/2 27 This may also permit analog measurement possibilities between two PC board nodes sampled at one time through the external AT1/2 27 pins.

One example of the signal level or waveform delivery path mentioned above, when the PROBE instruction is implemented, is shown in FIG. 3 and FIG. 4. The primary purpose of the 1149.4 PROBE instruction execution is to allow continuous-time access to pin signals, without affecting the mission mode, which is the functional mode of operation, (also referred to herein as “normal mode” or “functional mode”) of the IC and with the restriction that not more than two analog pins 304 may be sampled at one time (e.g., through external AT1 and AT2 pins 306). When the PROBE instruction is active, all DBMs 300 may be set to allow digital pins 301 to be connected to the core circuitry 302. All digital pins 301 are out of the PROBE instruction scope (as they may not be connected to ABMs 303). Execution of the PROBE instruction to allow continuous-time access to digital pin signals 301 may not be possible. ABMs 303 may be set to allow analog pins 304 to be connected to the core circuitry 302. Furthermore, the TBIC circuitry 305 switches may be also governed to allow AT1/2 306 to AB1/2 307 connections. ABM switch patterns are used by the PROBE instruction to connect none, one or both of the internal AB1/2 307 buses to the desired probing external analog pin 308.

The schematic example of enabling TBIC and ABM switches for AT2-to-pin signal probing path creation and AT1-to-pin signal injection path creation is shown in FIG. 4. The content 400 of the TBIC circuitry 414 control register may be used to connect AT1 pin 401 to AB1 bus 402 and to connect AT2 pin 403 to AB2 bus 404. Furthermore, ABM switch patterns 405 may be used to connect analog probing pin 406 (by switch 407) to AT2 pin 403, as well as to connect analog signal injecting pin 408 (by switch 409) to AT1 pin 401. The voltage 410 appearing on the in-circuit analog probing pin (node) 406 may be monitored in real time at the external AT2 pin 403 as the 411 voltage level or waveform. Similarly, the analog injecting signal 412, applied to the external AT1 pin 401, may be conveyed in real time to the in-circuit analog pin (node) 408 as voltage level or waveform 413.

1149.4 defines an analog bus that connects within each 1149.4-compliant IC (for example, as the result of a PROBE instruction execution) to analog I/O pins of the IC (but not to digital I/O pins) and may permit: a) an analog signal voltage level or waveform to be conveyed in real time from each such analog I/O pin to pins AT1 and/or AT2 and vice versa, as shown in FIG. 4, and to be monitored by an external test equipment. b) analog measurement implementation between two such analog I/O pins by connecting external measurement equipment to pins AT1 and AT2.

The capabilities of 1149.4 analog test bus have been described in several published papers, including “Complete, Contactless I/O Testing—Reaching the Boundary in Minimizing Digital IC Testing Cost” by S. Sunter et al, published in the 2002 ITC Proceedings (Nov. 1-6, 2002) incorporated herein by reference. As may be stated here, the value of the 1149.4 standard at the board level increases as more of the ICs on a board include these test facilities. However, the realities of the marketplace may prevent any new standard from being adopted at the IC level until it makes the IC cheaper to manufacture and test. Adding 1149.4 standard features to a mixed-signal IC may appear too expensive if it only addresses analog testing.

U.S. patent application Ser. No. 20030208708 Issued Nov. 6, 2003 for “Circuit and method for adding parametric test capability to digital boundary scan”, incorporated herein by reference, discloses, inter alia, that a drawback of existing circuits may be that a designer who wishes to provide analog access to digital IC pins that may be controlled by IEEE standard 1149.1-1990 (also referred to herein as “1149.1”) boundary scan, is compelled to use the dot-4 standard boundary scan cells, and accept the accompanying gate count penalty, in order to use conventional 1149.1 and 1149.4 software and hardware tools for performing boundary scan testing.

### SUMMARY OF THE INVENTION

Some embodiment of the invention may provide a method and apparatus for “virtual” in-circuit probing and testing of mixed-signal PC boards both in real time and off-line, as well as in-core probing and testing of mixed-signal IC cores without using the true ICT, manual probing or flying probe methods.

Some embodiments of the invention may provide penetrated testability and measurement access to mixed-signal PC boards and to mixed-signal core of ICs, wherein the testing approach may at least be partially compatible with boundary scan conventional techniques (for example, 1149.1, 1149.4, or other standards). The mixed-signal PC boards and IC's under test may be populated or not with one or more ICs compatible with conventional boundary scan techniques. The core of the mixed-signal IC under test may be equipped or not with conventional boundary scan circuitry.

Some embodiments of the present invention may provide signal voltage level or waveform delivery for both analog and digital signals in mixed-signal PC boards and in mixed-signal IC cores in a way that may be at least partially compliant with conventional boundary scan standards, for example, both 1149.1 and 1149.4 standards, or other standards.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be under stood by reference to the following detailed description when read with the accompanied drawings in which:

FIG. 1 is a prior art schematic illustration of the BGA packaged IC assembling on the multilayer PC board with the lack of access for signal probing;

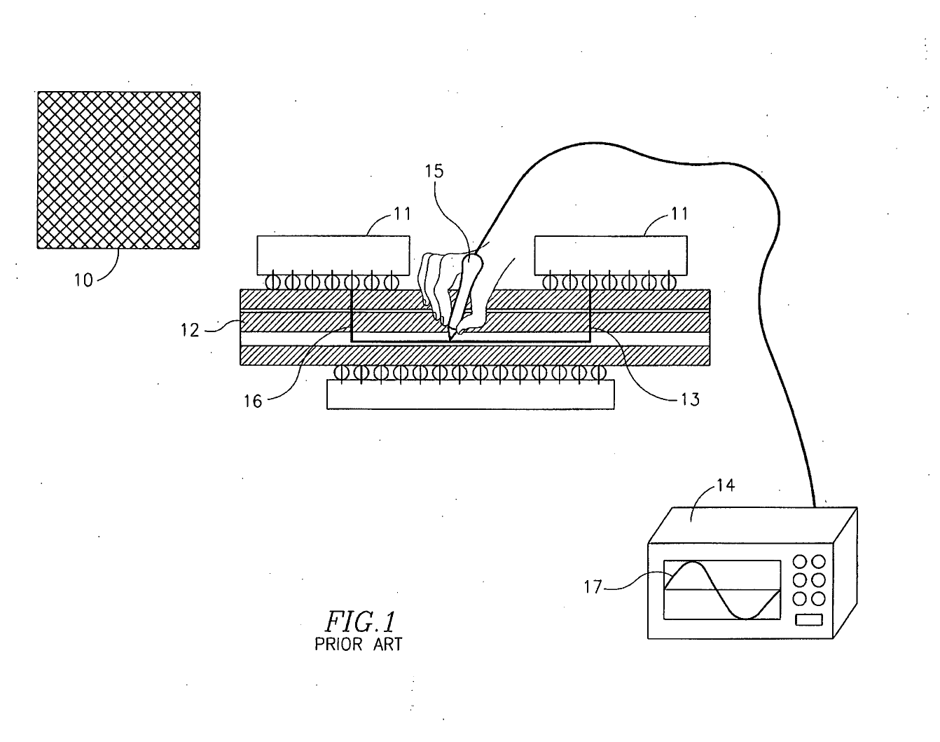

FIG. 2 is a prior art architecture illustration of 1149.4-compliant IC;

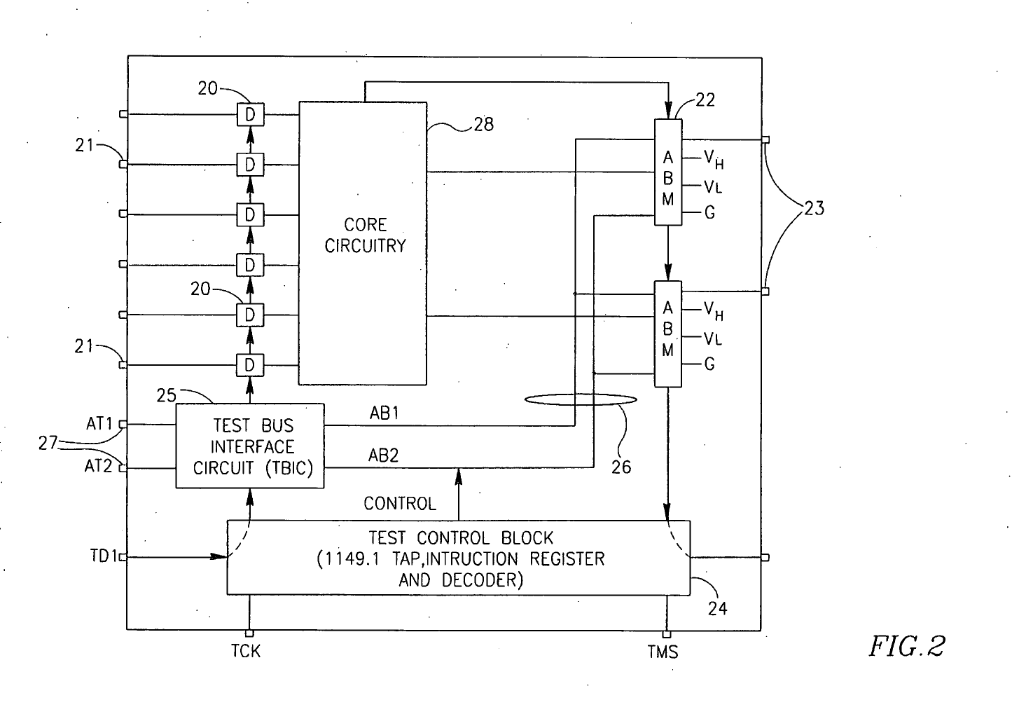

FIG. 3 is a prior art schematic illustration of the 1149.4 standard PROBE instruction implementation;

FIG. 4 is a prior art schematic illustration of enabling the 1149.4 standard TBIC and ABM switches for AT2-to-pin signal probing and for AT1-to-pin signal injection;

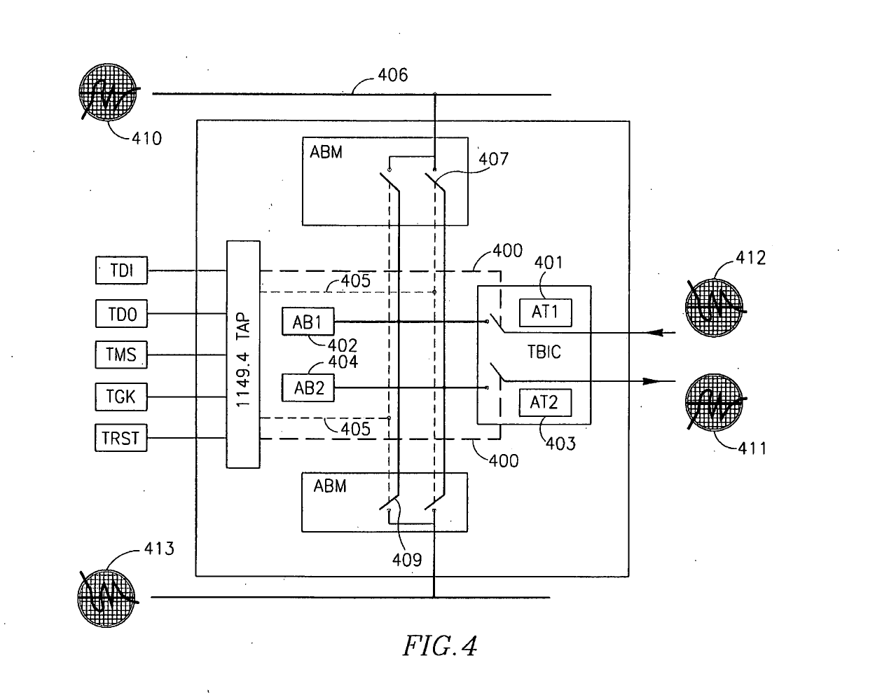

FIG. 5 is a schematic illustration of an integrated circuit in accordance with some embodiments of the present invention; and

FIG. 6 is a schematic illustration of a Design-for-Testability part of a functional integrated circuit in accordance with some embodiments of the present invention.

### DETAILED DESCRIPTION OF THE INVENTION

In the following detailed description, numerous specific details are set forth in order to provide a thorough understanding of the present invention. In other instances, well known methods, procedures, components and circuits have not been described in detail so as not to obscure aspects of the present invention.

One objective of an embodiment of the present invention is to add and facilitate the “virtual” (not physical) contact for in-circuit node probing and analog measurement capability implementation in mixed-signal PC boards and for in-core pin probing and analog measurement capability implementation in mixed-signal ICs in a way that may broaden standards such as 1149.4 standard; embodiments of the present invention may be relevant to other conventional boundary scan standards, for example, both 1149.1 and 1149.4 standards, or other standards.

A method according to some embodiments of the present invention may be able to add testing capability to mixed-signal electronic PC boards by using for example an IC The IC may include, for example, a node selection coder circuitry and a pin multiplexing circuitry and may be provided with, for example, two serially connected TAPs. The pin multiplexing circuitry may include plurality of analog multiplexers; the first TAP circuitry may be supported by the 1149.4 boundary scan architecture or another suitable standard for selectively connecting one of the electronic PC board nodes to one of the external analog test buses, for example, AT1 or AT2 of the IC. The second TAP circuitry may be supported by the 1149.4 or 1149.1 boundary scan standards architecture and may be use for node selection coder circuitry implementation. When the node-under-test is selected by the second TAP circuitry, an instruction, for example, the standard PROBE instruction may provide connection of the selected node to one of the analog test buses of the IC through first TAP circuitry. The second TAP circuitry may include plurality of digital boundary modules each connected to address inputs of at least a first multiplexer and a second multiplexer. Some embodiments may provide the penetrated testability access to the selected nodes by signal voltage level or waveform delivery both for probing of the signal levels or waveforms (both digital and analog) on these in-circuit nodes and for signal insertion to those nodes, as well as for analog measurement implementation on the selected nodes.

In accordance with some embodiments of the present invention, an IC or a Design-for-Testability part of any functional IC may be provided with pin multiplexer circuitry for selectively connecting one of in-circuit PC board nodes to one of external IC test buses, for example, AT1 or AT2. The selection may be accomplished by, for example, providing a node selection command in boundary scan 1149.1 or 1149.4-style protocol through pin TDI to the node selection coder. As a function of the node selection code, the node multiplexers circuitry connects the appropriate external IC pin (e.g., connected to the in-circuit PC board node selected) to the IC internal 1149.4 circuitry. Furthermore an instruction, for example, the standard PROBE instruction of 1149.4 boundary scan protocol through pin TDI provides connection of this IC pin (e.g., connected to the in-circuit PC board node selected) to one of IC external test buses AT1 or AT2. These buses may be connected to a PC board's external pins as well. Other standards may be used or modified.

In accordance with some embodiments of the present invention, a Design-for-Testability part of any functional IC may be provided with pin multiplexer circuitry for selectively connecting one of the IC external pins or internal core pins to one of external IC test buses AT1 or AT2. The selection may be accomplished by, for example, providing a pin selection command in boundary scan 1149.1 or 1149.4-style protocol through pin TDI to the pin selection coder. As a function of the pin selection code, the pin multiplexer circuitry connects the appropriate IC external pin or internal core pin to the IC internal 1149.4 circuitry, so that the standard PROBE instruction in 1149.4 boundary scan protocol through pin TDI provides connection of this IC pin or core internal pin to one of IC external test buses AT1 or AT2.

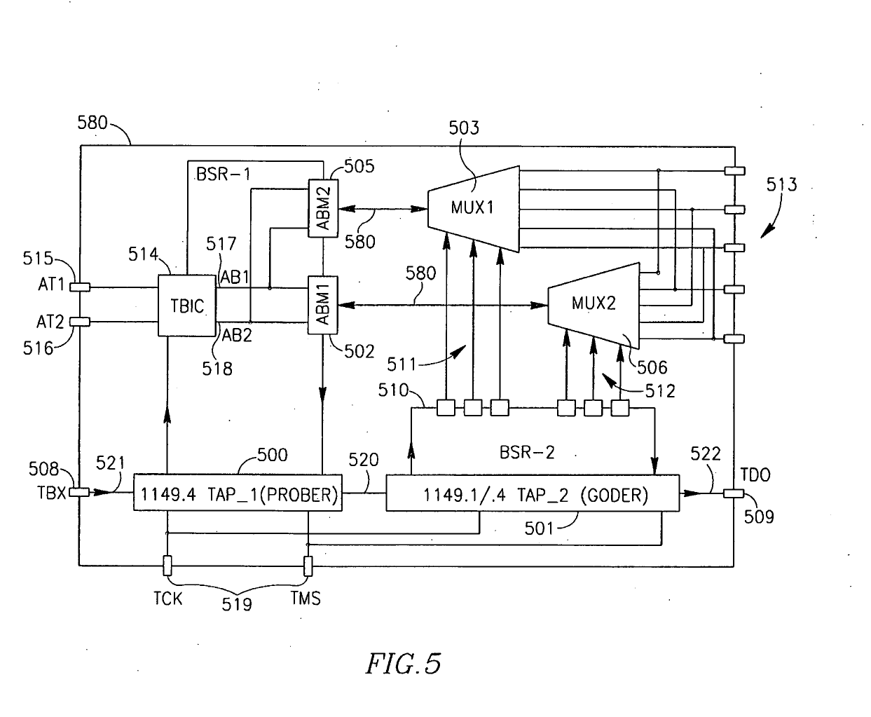

Reference is made now to FIG. 5 which is a schematic illustration of an integrated circuit in accordance with some embodiments of the present invention. An IC 580 may be provided with, for example, one 1149.4-compliant TAP_{—}1 circuitry 500 (also referred to herein as “Prober”), and with, for example, one 1149.1-compliant or 1149.4-compliant TAP_{—}2 circuitry 501 (also referred to herein as “Coder”). Although the scope of the present invention is not limited in this respect in some embodiments of the present invention, no functional core circuitry may be included in the IC except for the appropriate boundary scan circuitry. The TAPs and other circuitry may be compliant with 1149.4 or other standards or function in accordance with other standards.

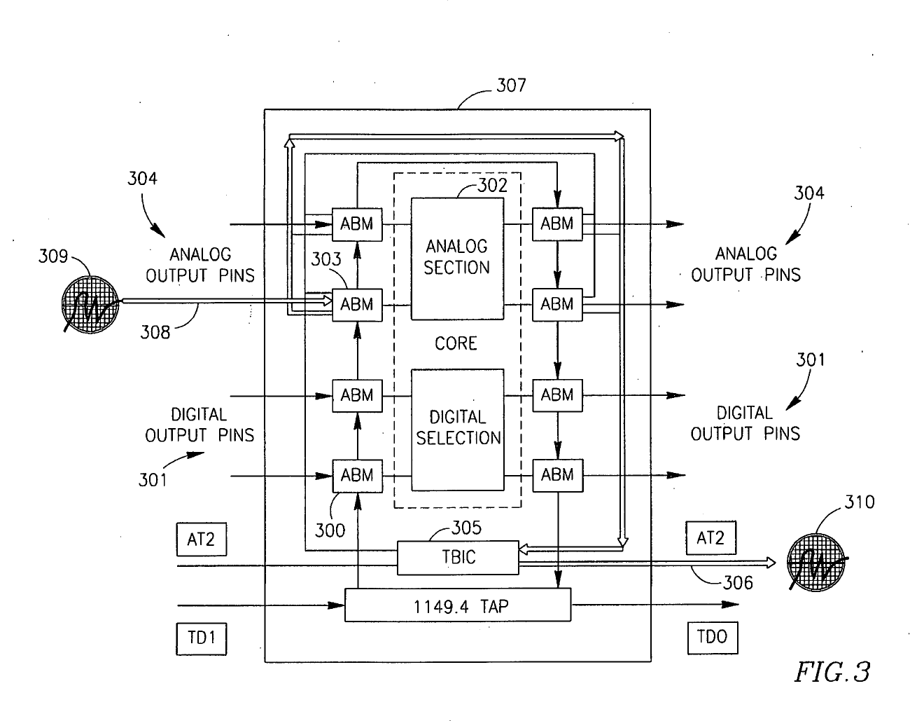

The boundary scan register (“BSR-1”) of the TAP_{—}1 circuitry 500 may not include digital boundary modules (see e.g. DBM 300 in FIG. 3), but at least two analog boundary modules (“ABM”) only. The first ABM1 502 may be connected to an analog multiplexer MUX_{—}2 506 through output bus 507. The second ABM2 505 may be connected to analog multiplexer MUX_{—}1 503 through output bus 504. The analog multiplexers may include any numbers of input/output connected to the external IC pins.

TDI input 521 of the TAP_{—}1 circuitry 500 may be connected to the external IC TDI pin 508, TDO output 520 of the TAP_{—}1 circuitry 500 may be connected to TDI input 520 of the TAP_{—}2 circuitry 501 (serial connection of TAP_{—}1 500 and TAP_{—}2 501), and TDO output 522 of the TAP_{—}2 circuitry 501 may be connected to the external IC TDO pin 509. Both TMS and TCK inputs 519 of both TAP circuitries may be connected in parallel and connected to external TMS and TCK input pins respectively. TMS and TSK inputs 519 may be compliant, for example with 1149.4 and/or 1149.1. At least a portion of BSR-2 510 of the TAP_{—}2 circuitry 501 may be connected to code or address inputs 511 of analog multiplexer MUX_{—}1 503 and another portion of BSR 510 of the TAP_{—}2 circuitry 501 may be connected to code or address inputs 512 of analog multiplexer MUX_{—}2 506. All analog inputs of both analog multiplexers MUX_{—}1 503 and MUX_{—}2 506 may be connected directly or in parallel to external IC I/O pins 513. All analog inputs of MUX_{—}1 503 may be connected in parallel to analog inputs of MUX_{—}2 506. The TAP_{—}1 circuitry 500 may include TBIC circuitry 514 (e.g., TBIC 305 in FIG. 3), a pair of external analog test buses AT1 515 and AT2 516, that may be connected to the IC corresponding external pins, and pair of internal test buses AB1 517 and AB2 518, that are connected to the ABM1 502 and ABM2 505 respectively. The TBIC circuitry 514 may include a switching circuitry which may be able to connect AB1/2 to AT1/2 as desired. The control of TBIC circuitry 514 may be provided by applying, for example, a PROBE instruction according to the 1149.4 standard.

According to some embodiments of the present invention, when the PC board that may include IC 580 is in mission mode and the IC 580 is in mode of no usage (also referred to herein as “shadow mode”), the TAP_{—}1 circuitry 500 may be in a reset state, internal switches in the ABM1 502 and ABM2 505 may disconnect buses 504 and 507 from internal test buses AB1 517 and AB2 518 respectively. Furthermore internal switches of TBIC circuitry 514 may disconnect internal test buses AB1 517 and AB2 518 from external test buses AT1 515 and AT2 516 respectively. In mission mode multiplexer's 503 and 506 inputs 511 and 512 respectively may be tristated (because of a reset state of the TAP_{—}2 circuitry 501), which may lead all external IC I/O pins 513 to be disconnected from multiplexer output buses 504 and 507.

According to some embodiments of the present invention, when IC 580 is in use (the PC board that may comprise IC 580 may work in mission mode or in testing mode) a boundary scan sequence may be applied to the external IC TDI pin 508, for example a boundary scan sequence compliant with 1149.1 or 1149.4. The boundary scan sequence applying may include shifting into the instruction register of TAP-2 circuitry 501, for example, the PRELOAD instruction, followed by address codes for analog multiplexers 503 and 506 inputs. Other suitable instructions may be used. The applied standard boundary scan sequence may not interrupt the PC board mission mode. These preloaded addresses may define IC 580 external I/O pins 513 selected to be multiplexed to one, both or none of ABM1 502 and ABM2 505. These address codes may be captured and clamped in the boundary scan register (BSR-2) 510 as a result of shifting, for example, the CLAMP instruction code compliant with 1149.1 or 1149.4-style. Shifting, for example, the CLAMP instruction code into the instruction register of TAP-2 circuitry 501 may result in applying the code inputs of analog multiplexers 503 and 506. As a result, selected IC external I/O pins 513 (e.g., one, two or none) may be connected to MUX_{—}1 503 output bus 504, or to MUX_{—}2 506 output bus 507, or to both, or to none. Other suitable methods for controlling or addressing the multiplexer or multiplexers may be used. In some embodiments of the invention the EXTEST instruction code may also be used. A different number of multiplexers, TAP's circuitry, ABMs, AT buses, AB buses, I/O pins, or any other components may be used

According to some embodiments of the invention an instruction for enabling the TBIC circuitry 514 and one, both or none ABM1 502 and ABM2 505 switches may be applied, for example, the PROBE instruction may be shifted into the instruction register of TAP-1 circuitry 500. The following paths may be created as a result, according to multiplexer address code preloaded above:

AT1 515<->AB1 517<->ABM1 502<->Mux_{—}2 506<->selected external IC I/O pin 513

AT2 516<->AB2 518<->ABM2 505<->Mux_{—}1 503<->selected external IC I/O pin 513

Other suitable pathways may be used. Furthermore, instructions other than a “PROBE” instruction may be used. When the PROBE or other suitable instruction is executed, one, two or none of selected external IC I/O pins 513 (e.g., connected to the in-circuit PC board selected nodes) may be connected respectively to one, two or none of external IC pins AT1 515 and AT2 516 for delivery, for example, signal levels or waveforms in real time and for analog measurement purposes.

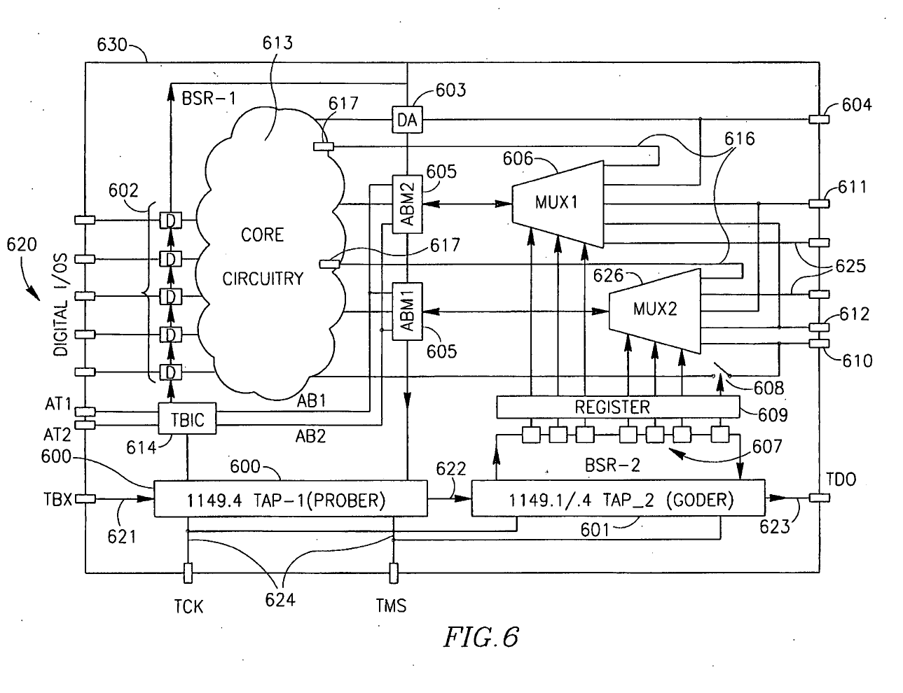

Reference is made now to FIG. 6 which is a schematic illustration of a Design-for-Testability part of a functional integrated circuit in accordance with some embodiments of the present invention. According to some embodiments of the invention functional IC 630 may include one or more 1149.4 standard or other suitable standard compliant TAP circuitries, for example. TAP-1 600 and TAP-2 601. The TAP-1 600 may be able to execute PROBE instruction and/or other suitable instructions, TAP-2 601 (e.g. 1149.1 or 1149.4 compliant) may be able to execute suitable instruction, for example, PRELOAD and CLAMP instructions or other suitable instructions. Other suitable instructions and standards may be used.

According to some embodiments of the present invention TDI input of the TAP_{—}1 circuitry 600 may be connected to the external IC TDI pin 621, TDO output of the TAP_{—}1 circuitry 600 may be connected to TDI input 622 of the TAP_{—}2 circuitry 601 (serial connection of TAP_{—}1 600 and TAP_{—}2 601). TDO output of the TAP_{—}2 circuitry 601 may be connected to the external IC TDO pin 623. Both TMS and TCK inputs of both TAP circuitries may be connected in parallel and connected to external TMS and TCK input pins 624 respectively.

According to some embodiments of the present invention the boundary scan register (BSR-1) of TAP-1 600 may include, in addition to TBIC 614, for example:
a) At least one digital boundary module 602 which may be connected to the functional IC “regular” digital I/O pin(s) 620.
b) At least one digital boundary module 603 which may be connected to a functional IC digital I/O pin(s) 604, for example, a 1149.4 compliant I/O pin(s).
c) At least one analog boundary module, for example, ABM1 605 and ABM2 605, connected to “regular” and/or “specific” I/O pin(s) 611, 612 and 610 via output of at least one analog multiplexer, for example, 606 and 626. The number of analog boundary modules may be equal to the number of analog multiplexers Additional components may be used. Any suitable number of I/O pins, may be used.

The BSR-2 of the TAP-2 circuitry 601 may include digital boundary modules (e.g, 1149.4-compliant) or boundary scan cells (e.g., 1149.1-compliant) 607. Digital boundary modules 607 may be connected to address code inputs of analog multiplexers 606 and 626 and may control input(s) of analog switch(es) 608 via register 609.

According to some embodiments of the invention, the functional IC 630 may include at least one functional digital I/O pin 604, for example, a 1149.4 compliant digital I/O pin which may be connected to any ABM through analog multiplexers 606 and/or 626 and may be connected to the IC core 613 via dedicated digital boundary module(s) 603. Functional IC 630 may include at least one analog I/O pin 610 which may be connected to any ABM through analog multiplexers 606 and/or 626 and may be connected to the IC core 613 via a dedicated switch 608. Furthermore, functional IC 630 may include at least one pin 625, which may not be IC 630 functional I/O pin but may be used as “in-circuit” prober and/or injector, for example, pin(s) 625 may not have functional use while IC 630 is in mission mode and may not be compliant with 1149.4. Pin(s) 625 (one, two or more) may provide the penetrated testability access to an in-circuit PC board nodes by signal voltage level or waveform delivery in real time. The penetrated testability access may be used for probing of the signal levels or waveforms (both digital and analog), for signal insertion into an in-circuit PC board node, and for in-circuit analog measurement implementation on the nodes mentioned herein.

According to some embodiments of the invention functional IC 630 may include a core circuitry 613 (also referred to herein as “functional core”). Core circuitry 613 may have an “in-core” prober and/or injector pin(s) 617, connected to inputs 616 of analog multiplexers 606 and 626. These “in-core” prober and/or injector pin(s) 617 may be other than core circuitry 613 functional pins (not shown) and may be used for testing and probing purposes not related to the mission mode of core circuitry 613. The “in-core” prober and/or injector pin(s) 617 may not be compliant with 1149.4. Pins 617 may provide a penetrated testability access for core circuitry 613 testing by in-core probing of the signal levels or waveforms (both digital and analog) and for signal applying into core circuitry 613, and for an in-core analog measurement implementation inside of an IC 630 functional core circuitry 613.

The functional IC 630 may include, for example, one, two or more analog I/O pin(s) 611 and 612 which may be connected to one, two or mote ABM1 and ABM2 respectively through one, two or more analog multiplexer(s) 606 and 626. Pins 611 and 612 may be compliant with 1149.4. All N inputs of analog multiplexers 606 and 626 may be connected directly or in parallel to the functional IC 630 external I/O pins 604 and/or 610 and/or 611 and/or 612 and/or 625 and/or to the internal I/O pin(s) 617.

Although the scope of the present invention is not limited in this respect at least five uses of pins may be included, for example:
a) Regular functional use of pins 604 and/or 610 and/or 611 and/or 612 when IC 630 is in mission mode of operation.
b) Testing use of pins 604 and/or 610 and/or 611 and/or 612 and/or 625, such as signal voltage level or waveform delivery in real time both for probing of the signal levels or waveforms and for signal insertion into an in-circuit PC board node (both for analog and digital pins).
c) Testing use of pin(s) 604 and/or 610 and/or 611 and/or 612 and/or 625 for the in-circuit board level test purposes, such as the in-circuit analog measurement implementation.
d) Testing use of internal pin(s) 617 for core circuitry 613 test purposes, such as the in-core signal voltage level or waveform delivery in real time both for probing of the signal levels or waveforms (both digital and analog) and for signal insertion into an IC 630 functional core 613.
e) Testing use of internal pin(s) 617 for an in-core IC 630 core 613 test purposes, such as the in-core analog measurement implementation.
Other functionality or uses may be included.

According to some embodiments of the present invention, one or more of N inputs of analog multiplexers 606 and 626 may be connected to analog I/O pins 611 and/or to analog I/O pins 612. These one, two or more selected analog I/O pins 611 and 612 may have full 1149.4 support through one or both of analog boundary modules ABM1 605 and ABM2 605 respectively, or through an additional analog boundary modules. These pins may be used both for the in-circuit board level test purposes and for connection to core circuitry 613 when the functional IC 630 is in its mission mode of operation. Core circuitry 613 may be working in mission mode of operation while pins 611 and/or pins 612 are connected to ABM1 and/or ABM2 605 according to the preload address codes provided to analog multiplexers 606 and/or 626.

According to some embodiments of the present invention digital I/O pins 604 may be connected to one or more of N inputs of analog multiplexers 606 and/or 626 and to the corresponding digital boundary modules 603 (a digital boundary modules 603 for each digital I/O pin 604). When the functional IC 630 is in, for example, mission mode of operation, each digital I/O pin 604 may be connected to core circuitry 613 via corresponding digital boundary module(s) 603 (e.g., according to 1149.4, 1149.1 or other suitable standard protocol) and may be disconnected from ABM1 and/or ABM2 605 according to the proper address code provided on analog multiplexers 606 and/or 626 code inputs. For in-circuit board level test purposes, the digital I/O pin(s) 604 may be isolated from core circuitry 613 by the digital boundary module(s) 603 through, for example, 1149.4 or 1149.1 standard protocol, while being connected to one or more inputs of analog multiplexers 606 and/or 626, and may be used for in-circuit board level test purposes according to the proper address code provided on analog multiplexers 606 and/or 626 code inputs. Core circuitry 613 may continue to work in mission mode of operation while the above connections are made.

According to some embodiments of the present invention analog I/O pins 610, may be connected to one, two or more of the N inputs of analog multiplexers 606 and/or 626 and to the dedicated analog switch 608 (608 may represent at least one switch). When core circuitry 613 works in mission mode of operation, each analog I/O pin 610 may be connected to the functional core circuitry 613 via corresponding closed analog switch(es) 608 and may be disconnected from ABM1 and/or ABM2 605 according to the proper address code provided on analog multiplexers 606 and/or 626 code inputs. For the in-circuit board level test purposes, the analog I/O pin(s) 610 may be isolated from the functional core circuitry 613 by the opened analog switch(es) 608, while being connected to one or more of inputs of analog multiplexers 606 and/or 626, and may be used for the in-circuit board level test purposes according to the proper address code provided on analog multiplexers 606 and/or 626 code inputs being connected to ABM1 and/or ABM2 605, for example, may be compliant with 1149.4 implementation for these pins. This operation may not effect the core circuitry 613 mission mode operation.

Pins 625 (“in-circuit” prober and/or injector) may be digital or analog external I/O pins, which may have testing capabilities and/or purposes and may have no functional usage of core circuitry 613. For example, pins 625 may be connected to one or mote of inputs of analog multiplexers 606 and/or 626. Furthermore pins 625 may be used for the in-circuit board level test purposes according to the proper address code provided on analog multiplexers 606 and/or 626 being connected to ABM1 and/or ABM2 605. For example, pins 625 may be used as 1149.4 compliant pins or other suitable standards. This usage may not effect core circuitry 613 mission mode operations.

Pins 617 (“in-core” prober and/or injector) may be digital or analog internal core circuitry 613 pins, which may have testing capabilities and/or purposes and may have no functional usage of the core circuitry 613. For example, pins 617 may be connected to one or more of inputs of analog multiplexers 606 and/or 626. Furthermore, pins 617 may be used for the in-core IC 630 test purposes according to the proper address code provided on analog multiplexers 606 and/or 626 being connected to ABM1 and/or ABM2 605. This usage may not effect core circuitry 613 mission mode operations.

Although the scope of the present invention is not limited in this respect when IC 630 is powered up, the register 609 may supply hardwired address codes of analog I/O pins 611 and/or 612 to the inputs of analog multiplexers 606 and/or 626 respectively, and control signals to analog switches 608. For example, in a regular 1149.1 or 1149.4-style boundary scan mode both TAP-1 600 and TAP-2 601 may be in a reset state, so the functional IC 630 may be ready to work in mission mode of operation.

According to some embodiments of the present invention the start step of using IC 630 for the in-circuit board level test purposes may include, for example, using a loading instruction, for example, PRELOAD instruction of 1149.1 or 1149.4 standards or another suitable instruction. The PRELOAD instruction may be shifted into the instruction register of TAP-2 circuitry 601, followed by, for example, the address for analog multiplexers 606 and/or 626 inputs, and, for example, an open control signals for corresponding analog switches 608. The loaded address for analog multiplexers 606 and/or 626 and corresponding analog switches 608 may define the required functional IC 630 external digital and/or analog I/O pin(s) 604 and/or 610 and/or 611 and/or 612 and/or 625 to be multiplexed to ABM1 and/or ABM2 605 for the in-circuit board level test purposes use, or may define the required IC 630 internal digital and/or analog I/O pin(s) 617 to be multiplexed to ABM1 and/or ABM2 605 for the in-core IC 630 test purposes use. For example, if any IC 630 I/O pin(s) 604 and/or 610 and/or 611 and/or 612 and/or 625 and/or pin(s) 617 required to be multiplexed, a suitable address for analog multiplexers 606 and/or 626 and/or an open control signals to analog switches 608 may be supplied. This address code may be captured and clamped in the boundary scan register (BSR) 607 after, for example, the CLAMP instruction or another suitable instruction is shifted into the instruction register of TAP-2 circuitry 601, and may be applied through register 609 to analog multiplexers 606 and/or 626 inputs and/or to corresponding analog switches 608.

Use of the IC 630 external pin(s) 604 and/or 610 and/or 611 and/or 612 and/or 625 for the in-circuit board level test purposes, or use of internal pin(s) 617 for the in-core IC 630 test purposes may include, for example, using an instruction, for example, a PROBE instruction, which may be shifted into, for example, the instruction register of TAP-1 circuitry 600. This instruction may enable TBIC 614 and ABM1 and/or ABM2 605 switches (e.g., according to 1149.4 standard protocol or other suitable protocol) and may create the following signal paths:

AT1 615<->AB1 631<->ABM1 605<->Mux2 626<->selected external IC 630 I/O pins of type 604 or 610 or 611 or 612 or 625 or selected internal IC 630 I/O pin of type 617.

AT2 615<->AB2 631<->ABM2 605<->Mux1 606<->selected external IC 630 I/O pins of type 604 or 610 or 611 or 612 or 625 or selected internal IC 630 I/O pin of type 617.

Other probing paths may be used; other numbers of pins may be used and tested.

According to some embodiments of the present invention when, for example, a PROBE instruction performed, one or two of selected external IC 630 I/O pin(s), e.g., 604 and/or 610 and/or 611 and/or 612 and/or 625 pins, or selected internal IC 630 I/O pin(s) 617, are connected respectively to one or two IC 630 pin(s) AT1 and/or AT2 615 for delivery signal levels or waveforms in real time both for the in-circuit board level test purposes and for the in-core test purposes, as well as for the in-circuit and in-core analog measurement purposes. Although the scope of the present invention is not limited in this respect functional IC 630 core circuitry 613 may continue to operate in mission mode of operation.

While certain features of the invention have been illustrated and described herein, many modifications, substitutions, changes, and equivalents will now occur to those skilled in the art. It is, therefore, to be understood that the appended claims ale intended to cover all such modifications and changes as fall within the true spirit of the invention.

What is claimed is:

1. An integrated circuit comprising:
pin multiplexing circuitry;
a first test access port circuitry comprising at least two analog boundary modules;
a second test access port circuitry comprising a plurality of digital boundary modules each of said digital boundary modules connected to address inputs of at least a first multiplexer and a second multiplexer; and
a plurality of digital and analog input-output pins, connected to an external test bus via the multiplexing circuitry.

2. The integrated circuit of claim 1, wherein the first test access port circuitry and the second test access port circuitry are serially connected.

3. The integrated circuit of claim 1, wherein the first test access port circuitry comprises at least one test bus interface circuit.

4. The integrated circuit of claim 1, wherein the multiplexing circuitry comprises a plurality of analog multiplexers.

5. The integrated circuit of claim 1, comprising a plurality of digital or analog input-output pins, each connected to inputs of the first multiplexer, the first multiplexer connected to the first analog boundary nodule, the first analog boundary module connected to an external test bus via an internal test bus and via the test bus interface circuit of the first test access port circuitry.

6. The integrated circuit of claim 4, wherein the plurality of digital input-output pins are each connected to inputs of the first multiplexer and to the digital boundary module in parallel.

7. The integrated circuit of claim 1, wherein a plurality of analog input-output pins are each connected to inputs of the second multiplexer via a switch, the second multiplexer is connected to the second analog boundary module, the second analog boundary module is connected to an external test bus via an internal test bus and the test bus interface circuit of the first test access port circuitry.

8. The integrated circuit of claim 1 wherein the input-output pins are external input-output pins.

9. The integrated circuit of claim 1 wherein the input-output pins are internal input-output pins.

10. The integrated circuit of claim 1 wherein the inputs of the first multiplexer are connected in parallel to the inputs of the second multiplexer.

11. The integrated circuit of claim 1 wherein the plurality of digital boundary modules of the second test access port circuitry are each connected to address inputs of at least a first multiplexer and a second multiplexer via a register;

12. The integrated circuit of claim 10 wherein the register is to store an address code.

13. The integrated circuit of claim 10 wherein the plurality of digital boundary modules of the second test access port circuitry and the register are to supply an address code to the pin multiplexing circuitry.

14. The integrated circuit of claim 1 comprising a core.

15. The integrated circuit of claim 14, wherein the analog boundary modules are connected to the core.

16. The integrated circuit of claim 14, comprising a switch between an external analog input-output pins and the core.

17. The integrated circuit of claim 16, wherein when the switch is open, the analog input-output pins are connected to an external test bus via the first multiplexer and an analog boundary module.

18. The integrated circuit of claim 16, wherein when the switch is closed, the analog input-output pins are connected to the core in normal mode of operation.

19. A method for selecting a set of input-output pins of an integrated circuit to be connected via an analog multiplexer to an analog boundary module and to analog test bus or a core, the method comprising:
storing an address code in a register and supplying the address code to a set of multiplexers; and
controlling an analog switch to connect and disconnect an external analog input-output pin to a core.

20. The method of claim 19, wherein the input-output pin is an analog pin or a digital pin.

21. The method of claim 19, wherein the input-output pin is an external pin or an internal pin.

22. The method of claim 19, wherein the integrated circuit is application-specified integrated circuit or a functional integrated circuit.

23. The method of claim 19, wherein storing an address code comprises delivering address code by a user.

24. The method of claim 19, wherein storing of a control code of the switch comprises delivering the control code by a user.

25. The method of claim 19, comprising connecting, via a set of multiplexers, selected input-output pins to a set of analog boundary modules.
